(19) United States
(12) Patent Application Publication
(10) Pub. No.: US 2010/0221494 A1
(43) Pub. Date: Sep. 2, 2010

(54) METHOD FOR FORMING SEMICONDUCTOR LAYER

(75) Inventors: Chang-Ming Lu, Pingtung County (TW); Chih-Wei Chao, Taipei City (TW); Te-Chung Wang, Taichung County (TW); Kuo-Lung Fang, Hsinchu County (TW); Chun-Jong Chang, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: LEXTAR ELECTRONICS CORP., Hsinchu City (TW)

(21) Appl. No.: 12/465,655

(22) Filed: May 14, 2009

(30) Foreign Application Priority Data
Feb. 27, 2009 (TW) 98106461

(51) Int. Cl. B32B 3/00; H01L 21/20

(52) U.S. Cl. 428/156; 438/481; 257/E21.094

(57) ABSTRACT

A method for forming a semiconductor layer includes following steps. First, an epitaxial substrate having at least a first growth region and at least a second growth region is provided. An area ratio of C plane to R plane in the first growth region is greater than 52/48. An epitaxial process is then performed on the epitaxial substrate to form a semiconductor layer. During the epitaxial process, a semiconductor material is selectively grown on the first growth region, and then the semiconductor material is laterally overgrown on the second growth region and covers the same.

### CROSS-REFERENCE TO RELATED APPLICATION

This application claims the priority benefit of Taiwan application serial no. 98106461, filed on Feb. 27, 2009. The entirety of the above-mentioned patent application is hereby incorporated by reference herein and made a part of specification.

### BACKGROUND OF THE INVENTION

1. Field of the Invention

The present invention relates to an epitaxial substrate and a method for forming a semiconductor layer of the epitaxial substrate. More particularly, the present invention relates to an epitaxial substrate capable of reducing lattice dislocation and a method for forming a semiconductor layer of the epitaxial substrate.

2. Description of Related Art

With progress in semiconductor technologies, a light emitting diode (LED) now has advantages of high luminance, low power consumption, compactness, low driving voltage, mercury free, and so forth. Therefore, the LED has been extensively applied in the field of displays and illumination. In general, an LED chip is fabricated by using a broad band-gap semiconductor material, such as gallium nitride (GaN) and the like. Nonetheless, in addition to the difference in thermal expansion coefficient and chemical properties, the difference between lattice constant of GaN and that of a hetero-substrate cannot be ignored as well. Hence, due to lattice mismatch, GaN grown on the hetero-substrate undergoes lattice dislocation, and the lattice dislocation extends toward a thickness direction of the GaN layer. As such, the lattice dislocation reduces the light emitting efficiency of the LED and shortens lifetime thereof.

FIGS. 1A to 1C are schematic views illustrating a conventional epitaxial process. Referring to FIG. 1A, a substrate 100 is provided, and a GaN buffer layer 110 is formed on the substrate 100. Next, a polycrystalline silicon oxide (SiO) mask layer 120 is deposited on the GaN buffer layer 110. Thereafter, a portion of the mask layer 120 is removed by photolithography and etching to form a plurality of mask patterns 120a on the GaN buffer layer 110 and to expose a portion of the GaN buffer layer 110, as shown in FIG. 1B. After that, an epitaxial process is performed, during which a GaN epitaxial layer 130 is grown on the other portion of the GaN buffer layer 110 not exposed by the mask patterns 120a, and the GaN epitaxial layer 130 is then laterally overgrown on the mask patterns 120a to cover the mask patterns 120a, as shown in FIG. 1C.

In the above-mentioned conventional process, the mask patterns 120a are employed to cut parts of the lattice dislocation, such that dislocation extending upwards is not apt to exist in a portion of the GaN epitaxial layer 130 disposed above the mask patterns 120a, and that epitaxial defects are further prevented. However, in the conventional epitaxial process, the mask patterns 120a are formed by implementing a photolithography and etching process. Thereby, fabrication is unlikely to be simplified, and costs can hardly be reduced.

### SUMMARY OF THE INVENTION

The present application is directed to an epitaxial substrate and a method for forming a semiconductor layer of the epitaxial substrate to better prevent lattice dislocation from extending in a thickness direction.

In the present application, a method for forming a semiconductor layer includes following steps. First, an epitaxial substrate having at least a first growth region and at least a second growth region is provided. An area ratio of C plane to R plane in the first growth region is greater than 52/48. An epitaxial process is then performed on the epitaxial substrate to form a semiconductor layer. During the epitaxial process, a semiconductor material is selectively grown on the first growth region, and then the semiconductor material is laterally overgrown on the second growth region and covers the same.

According to an embodiment of the invention, an area ratio of C plane to R plane in the second growth region is less than 52/48.

According to an embodiment of the invention, the method for forming the semiconductor layer further includes forming a mask layer on the second growth region before the epitaxial process is performed.

According to an embodiment of the invention, the semiconductor material is selectively nucleated on the C plane in the first growth region, and the semiconductor material is laterally overgrown on the R plane in the first growth region and covers said R plane.

According to an embodiment of the invention, during the selective nucleation of the semiconductor material performed on the C plane in the first growth region, the semiconductor material is selectively nucleated on the C plane in the second growth region.

According to an embodiment of the invention, a taper of the first growth region is less than or equal to 35 degrees.

According to an embodiment of the invention, a taper of the second growth region is greater than 35 degrees.

According to an embodiment of the invention, the epitaxial process includes a metal organic chemical vapor deposition (MOCVD) process.

The present application further provides an epitaxial substrate. The epitaxial substrate has at least a first growth region and at least a second growth region. An area ratio of C plane to R plane in the first growth region is greater than 52/48.

According to an embodiment of the invention, an area ratio of C plane to R plane in the second growth region is less than 52/48.

According to an embodiment of the invention, a taper of the first growth region is less than or equal to 35 degrees.

According to an embodiment of the invention, a taper of the second growth region is greater than 35 degrees.

Based on the above, by adjusting an area ratio of a nucleated plane to a plane which cannot be nucleated, lattice dislocation extending in a thickness direction can be effectively reduced without performing additional manufacturing steps. Further, epitaxial defects can be better prevented.

In order to make the aforementioned and other features and advantages of the present invention more comprehensible, several embodiments accompanied with figures are described in detail below.

### BRIEF DESCRIPTION OF THE DRAWINGS

The accompanying drawings are included to provide a further understanding of the embodiments of the invention, and are incorporated in and constitute a part of this specification. The drawings illustrate embodiments of the invention and, together with the description, serve to explain the principles of the invention.

FIGS. 1A to 1C are schematic views illustrating a conventional epitaxial process.

FIG. 2A is a schematic partial cross-sectional view of a semiconductor substrate according to an embodiment of the present invention, and FIG. 2B is a schematic partial enlarged view of the semiconductor substrate according to an embodiment of the present invention.

FIG. 2C is a schematic view illustrating a microscopic structure of the semiconductor substrate depicted in FIG. 2B, and FIG. 2D is a schematic view illustrating a microscopic structure of the semiconductor substrate depicted in FIG. 2B after an epitaxial process is performed.

FIGS. 2E to 2F are schematic views illustrating an epitaxial process according to an embodiment of the present invention.

FIG. 3 is a schematic partial enlarged view of FIG. 2A according to another embodiment of the present invention.

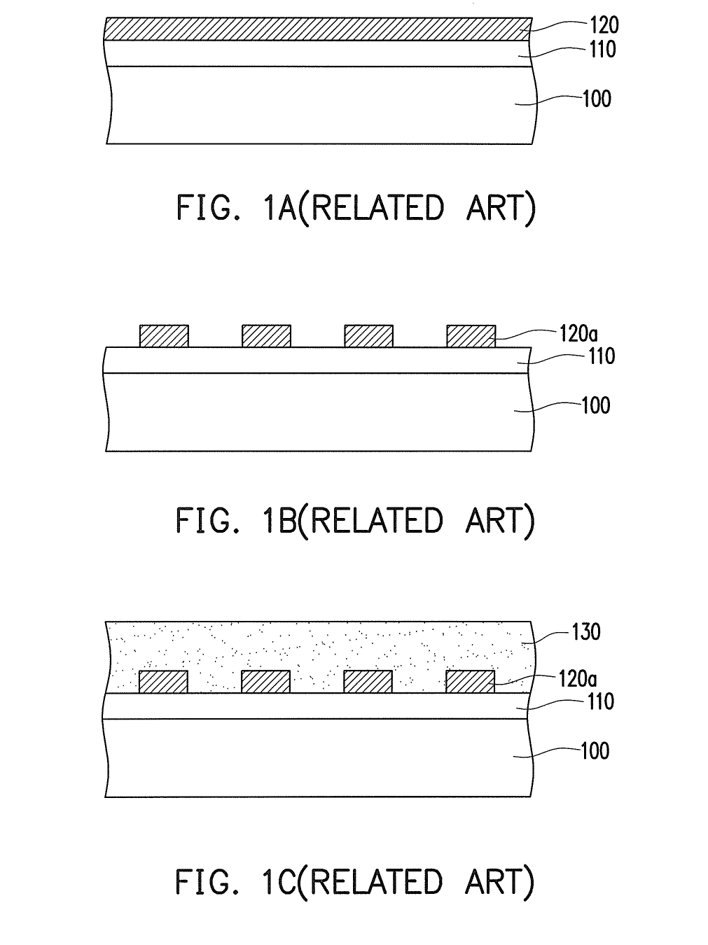

### DESCRIPTION OF EMBODIMENTS

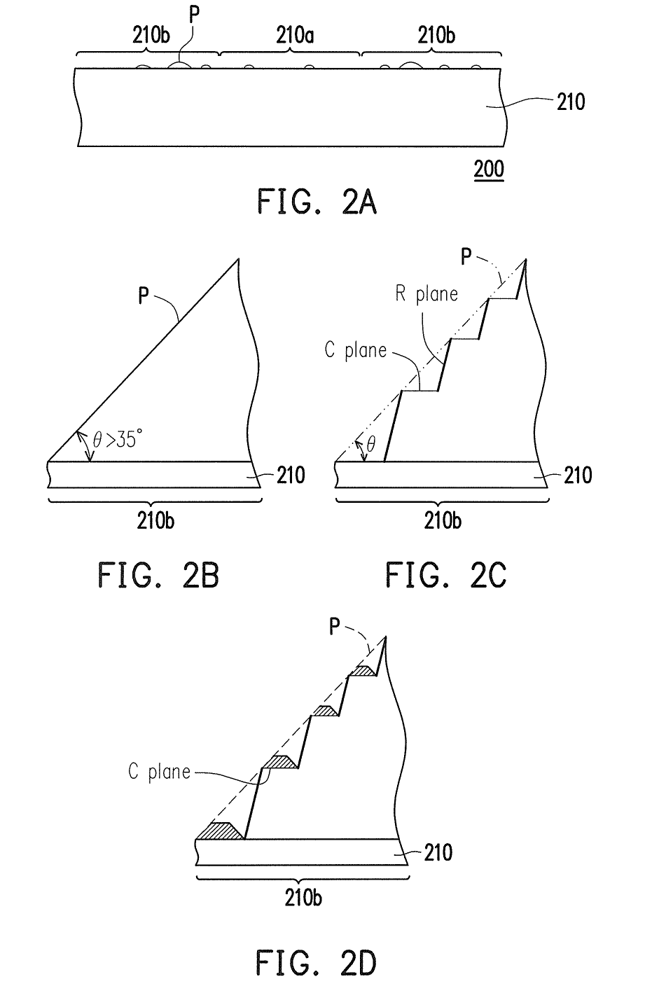

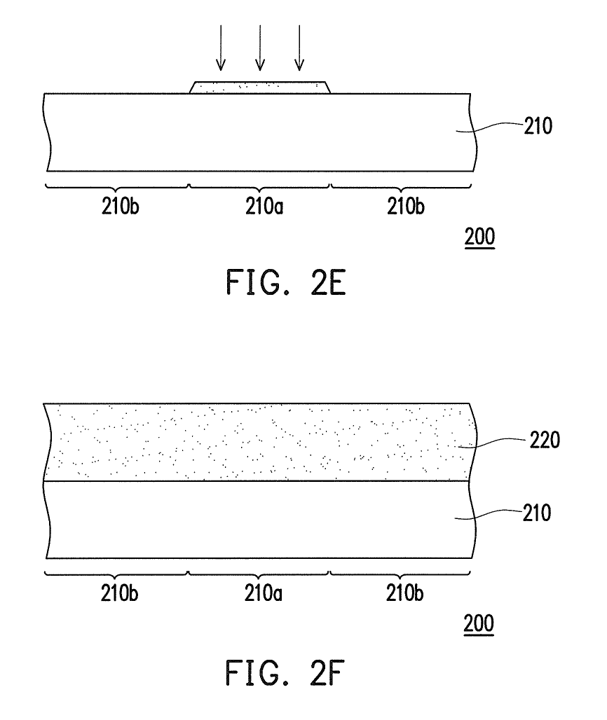

FIG. 2A is a schematic partial cross-sectional view of a semiconductor substrate 200 according to an embodiment of the present invention. Referring to FIG. 2A, first, an epitaxial substrate 210 is provided. The epitaxial substrate 210 has at least a first growth region 210a and at least a second growth region 210b. In the present embodiment, the substrate 210 is made of silicon, silicon carbide, aluminum oxide, glass, quartz, zinc oxide, magnesium oxide, or lithium gallium oxide.

In view of the above, an area ratio of C plane to R plane in the first growth region 210a of the substrate 210 is greater than 52/48. According to the present embodiment, an area ratio of C plane to R plane in the second growth region 210b is less than 52/48. To facilitate descriptions, schematic views illustrating macroscopic and microscopic structures of a portion of the second growth region 210b are provided as examples. The structure and the operation of the first growth region 210a are similar to those of the second growth region 210b. Note that the area ratio of the C plane to the R plane in the first growth region 210a is different from that in the second growth region 210b.

FIG. 2B is a schematic partial enlarged view of the second growth region 210b depicted in FIG. 2A, and FIG. 2C is a schematic view illustrating a microscopic structure of the second growth region 210b depicted in FIG. 2B. Referring to FIGS. 2A to 2C, a plurality of planes P having different shapes and inclinations are formed on the epitaxial substrate 210 depicted in FIG. 2A. Surfaces of the planes P seem to be smooth, as shown in FIG. 2B. Microscopically, however, the surfaces of the planes P have certain roughness, and the roughened planes P can be further divided into a plurality of planes, as shown in FIG. 2C.

FIG. 2D is a schematic partial enlarged view of performing an epitaxial process on the C plane depicted in FIG. 2C. Referring to FIGS. 2C to 2D, particularly, the planes that are further divided as shown in FIG. 2C can be substantially categorized into C plane and R plane. During performing of the epitaxial process, a plane on which the semiconductor material can be nucleated is defined as the C plane, while a plane on which the semiconductor material cannot be nucleated are defined as the R plane, as indicated in FIG. 2C. The semiconductor material on the R plane is not nucleated in the epitaxial process and thus cannot be accumulated and grown upwards. By contrast, the semiconductor material on the C plane is nucleated and thus can be accumulated and grown upwards until the thickness of the accumulated semiconductor layer exceeds a certain value. After that, the semiconductor material is laterally overgrown and accumulated on the adjacent R plane.

Generally, whether nucleation can be properly conducted on a unit area as a whole and whether the growth process can then well proceed are determined by adjusting area ratios of the nucleated planes to the planes which cannot be nucleated, i.e., by adjusting area ratios of the C plane to the R plane. When the area ratio of the C plane to the R plane is greater than 52/48, nucleation can be conducted on the unit area, and so can the semiconductor layer be grown thereon, e.g., on the first growth region 210a of the present embodiment. On the contrary, when the area ratio of the C plane to the R plane is less than 52/48, neither can nucleation be conducted on the unit area, nor can the semiconductor layer be grown thereon, e.g., on the second growth region 210b of the present embodiment. In this case, the semiconductor layer is grown on the adjacent semiconductor growth region (e.g., the first growth region 210a) and then laterally overgrown on the unit area.

Note that a taper of the first growth region 210a is less than or equal to 35 degrees in the present embodiment. Additionally, in the present embodiment, a taper of the second growth region 210b is greater than 35 degrees, as shown in FIG. 2B. Specifically, a taper between a plane and a horizontal axis is in substance inversely proportional to the area ratio of the C plane to the R plane. Namely, when the taper is greater than 35 degrees, the area ratio of the C plane to the R plane is less than 52/48; when the taper is less than 35 degrees, the area ratio of the C plane to the R plane is greater than 52/48.

FIGS. 2E to 2F are schematic views illustrating an epitaxial process according to an embodiment of the present invention. Referring to FIGS. 2E to 2F, in view of the foregoing, an epitaxial process is then performed on the epitaxial substrate 210 to selectively grow a semiconductor material on the first growth region 210a, as shown in FIG. 2E. According to the present embodiment, the epitaxial process includes a metal organic chemical vapor deposition (MOCVD) process. Besides, the semiconductor material is, for example, GaN. It should be mentioned that the semiconductor material is selectively nucleated on the C plane in the first growth region 210a according to the present embodiment, and then the semiconductor material is laterally overgrown on the R plane in the first growth region and covers the R plane.

Based on the above, after the semiconductor material is selectively grown on the first growth region 210a, the semiconductor material is then laterally overgrown on the second growth region 210b and covers the same, so as to form a semiconductor layer 220, as indicated in FIG. 2F. Moreover, in the present embodiment, during the selective nucleation of the semiconductor material conducted on the C plane in the first growth region 210a, the semiconductor material is selectively nucleated on the C plane in the second growth region 210b. Specifically, nucleation can be conducted on the C plane in the second growth region 210b during performing of the semiconductor epitaxial process. Nevertheless, the area ratio of the C plane to the R plane in the second growth region 210b is less than 52/48. Accordingly, epitaxial growth is in general not allowed in the second growth region 210b. Instead, the semiconductor material is epitaxially grown upwards in the first growth region 210a, and the semiconductor material is then laterally overgrown on the second growth region 210b and covers the same. At last, the semiconductor layer 220 is formed.

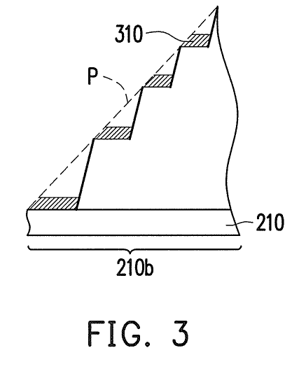

FIG. 3 is a schematic partial enlarged view of FIG. 2A according to another embodiment of the present invention. Referring to FIG. 3, the method for forming the semiconductor layer further includes forming a mask layer 310 on the second growth region 210b prior to performing of the epitaxial process. In detail, a material of the mask layer 130 can be silicon oxide, silicon nitride, and so on. Besides, the mask layer 130 can be selectively formed on certain areas. Thereby, the proportion of the originally nucleated C plane is reduced, and a range of lateral growth is thus increased. The lattice dislocation is not able to extend upwards in the lateral growth region, and therefore favorable epitaxial quality can be achieved in the lateral growth region.

In light of the foregoing, the substrate that is equipped with the planes having different shapes and inclinations is used in the method for forming the semiconductor layer according to the application. Since different nucleation properties exist in different crystalline facets, the lattice dislocation extending in the thickness direction can be effectively reduced by adjusting the proportion of the nucleated plane to the plane which cannot be nucleated, and epitaxial defects are further prevented. The substrate itself has a plurality of planes, and it is not necessary to additionally form mask patterns on the substrate by etching with use of photomasks. As a result, the semiconductor layer can be formed on the substrate by performing relatively few steps, thus resulting in reduction of the manufacturing costs and simplification of the manufacturing process.

Although the present invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A method for forming a semiconductor layer, the method comprising:
providing an epitaxial substrate having at least a first growth region and at least a second growth region, wherein an area ratio of C plane to R plane in the first growth region is greater than 52/48; and
performing an epitaxial process to form a semiconductor layer on the epitaxial substrate, wherein during the epitaxial process, a semiconductor material is selectively grown on the first growth region, and the semiconductor material is laterally overgrown on the second growth region and covers the second growth region.

2. The method as claimed in claim 1, wherein an area ratio of C plane to R plane in the second growth region is less than 52/48.

3. The method as claimed in claim 1, further comprising forming a mask layer on the second growth region before the epitaxial process is performed.

4. The method as claimed in claim 1, wherein the semiconductor material is selectively nucleated on the C plane in the first growth region, and the semiconductor material is laterally overgrown on the R plane in the first growth region and covers the R plane in the first growth region.

5. The method as claimed in claim 4, wherein during the selective nucleation of the semiconductor material performed on the C plane in the first growth region, the semiconductor material is selectively nucleated on C plane in the second growth region.

6. The method as claimed in claim 1, wherein a taper of the first growth region is less than or equal to 35 degrees.

7. The method as claimed in claim 1, wherein a taper of the second growth region is greater than 35 degrees.

8. The method as claimed in claim 1, wherein the epitaxial process comprises a metal organic chemical vapor deposition (MOCVD) process.

9. An epitaxial substrate having at least a first growth region and at least a second growth region, wherein an area ratio of C plane to R plane in the first growth region is greater than 52/48.

10. The epitaxial substrate as claimed in claim 9, wherein an area ratio of C plane to R plane in the second growth region is less than 52/48.

11. The epitaxial substrate as claimed in claim 9, wherein a taper of the first growth region is less than or equal to 35 degrees.

12. The epitaxial substrate as claimed in claim 9, wherein a taper of the second growth region is greater than 35 degrees.
